(19) United States
(12) Patent Application Publication
(10) Pub. No.: US 2020/0208258 A1
(43) Pub. Date: Jul. 2, 2020

(54) APPARATUSES, SYSTEMS AND METHODS FOR PROTECTING ELECTRONIC DEVICE ASSEMBLIES

(71) Applicant: HZO, Inc., Morrisville, NC (US)

(72) Inventors: Max Sorenson, Cottonwood Heights, UT (US); Blake Stevens, Morristown, NJ (US); Alan Rae, Wilson, NY (US); Marc Kenneth Chason, Schaumburg, IL (US); Dana Cox, American Fork, UT (US); James Kent Naylor, Kaysville, UT (US)

(21) Appl. No.: 16/818,783

(22) Filed: Mar. 13, 2020

Related U.S. Application Data
(63) Continuation of application No. 13/920,804, filed on Jun. 18, 2013.
Application No. 13/920,804 is a continuation of application No. 13/849,790, filed on Mar. 25, 2013.
Application No. 13/920,804 is a continuation-in-part of application No. 13/736,753, filed on Jan. 8, 2013, now Pat. No. 9,426,936.
(60) Provisional application No. 61/660,808, filed on Jun. 18, 2012.
(60) Provisional application No. 61/615,172, filed on Mar. 23, 2012.
(60) Provisional application No. 61/584,918, filed on Jan. 10, 2012.

(51) Int. Cl. C23C 16/02; B08B 17/06; C23C 16/04

(52) U.S. Cl. CPC C23C 16/02; B08B 17/06; H05K 3/284; C23C 16/0254; C23C 16/0227; C23C 16/042

(57) ABSTRACT

An apparatus for applying a protective coating to a high volume of separate electronic device assemblies includes a treatment element that is configured to prepare the high volume of electronic devices before protective coatings are applied to the electronic devices. The apparatus also includes a coating element configured to apply protective coatings to the high volume of separate electronic device assemblies.

### CROSS-REFERENCE TO RELATED APPLICATION

A claim for the benefit of priority to the Jun. 18, 2012 filing date of U.S. Provisional Patent Application 61/660,808, titled APPARATUSES AND SYSTEMS FOR APPLYING WATERPROOFING ELECTRONIC DEVICE ASSEMBLIES AND METHODS RELATING THERETO (“the '808 Provisional Application”), is hereby made pursuant to 35 U.S.C, §119(e), In addition, this application is a continuation-in-part of U.S. patent application Ser. No. 13/849,790, filed Mar. 25, 2013 and titled APPARATUS, SYSTEMS AND METHODS FOR APPLYING PROTECTIVE COATINGS TO ELECTRONIC DEVICE ASSEMBLIES (“the '790 Application”), in which a claim for the benefit of priority is made to the Mar. 23, 2013 filing date of U.S. Provisional Patent Application No. 61/615,172, titled APPARATUSES FOR WATERPROOFING ELECTRONIC DEVICE ASSEMBLIES AND METHODS (“the '172 Provisional Application”). This application is also a continuation-in-part of U.S. patent application Ser. No. 13/736,753, filed on Jan. 8, 2013 and titled SYSTEMS FOR ASSEMBLING ELECTRONIC DEVICES WITH INTERNAL MOISTURE RESITANT COATINGS (“the '753 Application”), which includes a claim for the benefit of priority under 35 U.S.C. §119(e) to U.S. Provisional Patent Application no. 61/584,918, filed on Jan. 10, 2012 and titled SYSTEMS FOR ASSEMBLING ELECTRONIC DEVICES WITH INTERNAL WATER-RESISTANT COATINGS (“the '929 Provisional Application”). The entire disclosures of the '808 Provisional Application, the '790 Application, the '172 Provisional Application, the '753 Application and the '929 Provisional Application are, by this reference, incorporated herein.

### TECHNICAL FIELD

This disclosure relates generally to apparatuses and systems for forming protective coatings and, more specifically, to coating apparatuses that are configured to be placed along assembly lines, to systems including the coating apparatuses and to methods for forming protective coatings on electronic devices. In particular, this disclosure relates to apparatuses, systems and methods in which an electronic device assembly, a plurality of electronic device assemblies or even a high volume of separate electronic device assemblies are treated before application of one or more protective coatings, or pre-treated, to alter a characteristic of each electronic device assembly.

### BACKGROUND

With the increased development of semiconductor device technology, electronic devices have played an important role in modern equipment, including portable electronic devices. For example, mobile phones have become important in the lives of many individuals, particularly with the advent of so-called “smart phones,” which enable a person to not only make and receive telephone calls, but also to view and create calendar events, receive and send e-mails, view and edit documents, access the internet and perform a variety of other functions regardless of the individual's location, provided only that the smart phone be in a location where it can receive and send data.

As the portability and use of portable devices has increased, so has the likelihood that portable devices may be damaged. For instance, when carrying a smart phone, tablet computing device, laptop, e-reader, digital camera, remote keyless entry (e.g., a car key, etc.), or other portable electronic device, or any other device, that device may be exposed to moisture from environmental conditions, or the portable electronic device may be accidentally dropped into a puddle, sink, toilet or other location where water or other moisture is present.

Although removable cases may be assembled with many portable electronic devices, removable cases often do not offer full protection against moisture. As a result, when a portable electronic device is exposed to moisture, the moisture can leak into the portable electronic device and damage components of the portable electronic device.

Moisture damage to a portable electronic device may impair its functionality or may cause the electronic device to cease operating entirely. Portable electronic devices may be expensive to replace. Indeed, the manufacturers' product warranties for most portable electronic devices do not cover exposure to moisture.

### SUMMARY

In one aspect, an apparatus for applying protective coatings may be configured to simultaneously apply protective coatings to and, optionally, otherwise process, a high volume (e.g., about one hundred (100) or more, about five hundred (500), about eight hundred (800) to about two thousand (2,000), etc., including more or fewer electronic device assemblies) of separate electronic device assemblies. Thus, the apparatus and each element thereof configured to receive electronic device assemblies may be configured for a so-called “high throughput.”

An apparatus that incorporates teachings of this disclosure includes an element for treating electronic device assemblies, and may include a coating application element. In some embodiments, the apparatus may include one or more elements for treating electronic device assembles before and/or after applying a protective coating to the electronic device assemblies and/or portions thereof. For the sake of simplicity, each such element is referred to herein as a “treatment element” and, unless such an element is inherently limited to being used before or after a protective coating is applied to an electronic device assembly, should not be considered to be so limited.

As used herein, the term “electronic device assembly” and similar terms may refer to fully assembled electronic devices or to partially assembled electronic devices, or electronic device subassemblies. A partially assembled electronic device, or electronic device subassembly, may, of course, comprise an electronic device that is only partway through an assembly process.

In some embodiments, the apparatus may be configured to treat one or more exposed surfaces of an electronic device assembly before applying protective coatings to those surfaces. Treatment may include removal of volatile compounds or other contaminants from surfaces of each electronic device assembly to which a protective coating is to be applied (e.g., by degassing or application of a vacuum to each electronic device assembly, by use of a plasma, by washing and drying, by otherwise cleaning at least portions of the electronic device assembly, etc.). A surface (e.g., its texture, etc.) of an electronic device assembly may be modified by treatment (e.g., by ablation, abrasion, polishing, etc.). An electronic device assembly may be treated by passivating or oxidizing one or more of its surfaces. Various types of treatments may be configured to impart a treated surface with one or more desired characteristics, such as an enhanced adhesion for a protective coating, a reduced adhesion for a protective coating, an ability to repel moisture, an ability to impart a protective coating applied thereto with an enhanced ability to resist moisture, or the like. Other types of treatment may include application of one or more masks or coating release elements to an electronic device assembly.

An apparatus that is configured to simultaneously apply protective coatings to surfaces of a high throughput of separate electronic device assemblies may be configured to impart at least a portion of each electronic device assembly with some degree of resistance to moisture. As used herein, the term “protective coating” includes moisture resistant coatings or films, as well as other coatings or films that protect various parts of an electronic assembly from moisture and/or other external influences. While the term “moisture resistant coating” is used throughout this disclosure, in many, if not all, circumstances, a moisture resistant coating may comprise or be substituted with a protective coating that protects coated components and/or features from other external influences. The term “moisture resistant” refers to the ability of a coating to prevent exposure of a coated element or feature to moisture. A moisture resistant coating may resist wetting or penetration by one or more types of moisture, or it may be impermeable or substantially impermeable to one or more types of moisture. A moisture resistant coating may repel one or more types of moisture. In some embodiments, a moisture resistant coating may be impermeable to, substantially impermeable to or repel water, an aqueous solution (e.g., salt solutions, acidic solutions, basic solutions, drinks, etc.) or vapors of water or other aqueous materials (e.g., humidity, fogs, mists, etc.), wetness, etc.). Use of the term “moisture resistant” to modify the term “coating” should not be considered to limit the scope of materials from which the coating protects one or more components of an electronic device. The term “moisture resistant” may also refer to the ability of a coating to restrict permeation of or repel organic liquids or vapors (e.g., organic solvents, other organic materials in liquid or vapor form, etc.), as well as a variety of other substances or conditions that might pose a threat to an electronic device or its components.

A coating application element of an apparatus according to this disclosure may be configured to non-selectively apply a protective coating to, or form a protective coating on, surfaces of an electronic device assembly (e.g., by “blanket coating” the protective coating onto all surfaces that are exposed to a protective material). Alternatively, the coating application element may be configured to apply the protective coating to, or form it on, selected portions of one or more surfaces of the electronic device assembly that are exposed to the protective material. A variety of different types of equipment may be employed as the coating application element of an apparatus that incorporates teachings of this disclosure. In some embodiments, the coating application element may comprise a deposition chamber and, for the sake of simplicity, may be referred to as such hereinafter. Without limitation, a coating application element may be configured to apply protective material by way of chemical vapor deposition (CVD), plasma-based deposition processes (including, but not limited to, plasma enhanced CVD (PECVD) processes), physical vapor deposition (PVD) or physical application (e.g., by spraying, rolling, printing, etc.) of the protective material.

Each element of an apparatus for simultaneously applying protective coatings to a high volume of separate electronic device assemblies may be carried by a frame, with the frame and the apparatus being configured for integration into a line (e.g., an assembly line, etc.) of a production facility. The apparatus may be configured for integration into a line without extending a significant distance (or any distance) into, or otherwise blocking, an aisle adjacent to either side of the line. Specifically, an apparatus for applying a protective coating may have a width of no more than about two or three meters.

Among other things, the frame of the apparatus may carry a conveyor, such as a track or other transport element. The transport element may be configured to carry a rack, which may, in turn, be configured to carry a high volume of separate electronic device assemblies. In some embodiments, a rack may include a plurality of shelves, each of which may be configured to hold one or more electronic device assemblies. The transport element may be configured to transport the rack and, thus, the electronic device assemblies, along a length of the apparatus. Specifically, the transport element may be configured to transport the rack into and out of any treatment element of the apparatus, and into and out of the coating application element. Of course, a conveyor that is separate from the apparatus may also be used to transport electronic device assemblies from one location to another. In either event, a conveyor may be configured for manual operation, or it may be automated.

In embodiments where the apparatus includes a transport element, the transport element may be configured to transport, and control a destination of, a rack, along with a high volume of separate electronic device assemblies thereon, or carried thereby. In some embodiments, the transportation element may be configured to direct the rack to, through and from a treatment element and to, through and out of a coating application element.

An apparatus may also include a material supply system with one or more components that supply water-resistant or other protective materials to the coating application element. Where the width of the apparatus enables it to be incorporated into a line, the material supply system may be positioned and/or oriented in a manner that minimizes the overall width of the apparatus. For example, and not by way of limitation, the material supply system may be positioned at a higher elevation than, or even above, a treatment element, if any, and the coating application element. Of course, the material supply system may be located elsewhere on the apparatus.

An apparatus that applies protective coatings to electronic device assemblies may be included in a variety of assembly and production systems. In an assembly or production system, components of an electronic device assembly may be assembled with one another or disassembled from one another, optionally treated, then introduced into a coating application element. Optionally, the electronic device assembly and/or the coating may be inspected (e.g., the electronic device assembly, upstream of or downstream from the coating application element; the protective coating, downstream from the coating application element). In some embodiments, an assembly or production system may include elements that enable further treatment (e.g., material removal, cleaning, drying, etc.) of an electronic device assembly, as well as further assembly of the electronic device assembly, including complete assembly thereof. Any or all elements of such as a system may be in-line with a line, or one or more elements of such a system may be off-line.

An electronic device assembly may be initially provided in a previously assembled state or a partially assembled state (i.e., it may comprise a subassembly), and some disassembly may be desirable before a protective coating is applied to the electronic device assembly and/or any components that have been removed therefrom. In such an embodiment, the system may include a disassembly element upstream from the coating application station. In the disassembly element, an electronic device assembly may be at least partially disassembled.

Methods for applying protective coatings to high volumes of separate electronic device assemblies are also disclosed, such a method may include some disassembly before applying the protective coating. Each electronic device assembly may be treated in a manner that will impart the electronic device assembly with one or more desired characteristics. After treatment, the high volume of separate electronic devices may be transported from a treatment element of an apparatus to a coating application element of the same apparatus. At the coating application element, protective coatings may be applied to the high volume of separate electronic devices. After protective coatings have been applied, each electronic device may be post-processed (e.g., by removing parts of a protective coating from surfaces, features or components that are to remain exposed through or laterally beyond a protective coating, to remove any masks, to remove residues remaining on the electronic device assembly after the application process, etc.). Each electronic device assembly and/or each protective coating thereon may be inspected and, optionally, subjected to further processing, as may be appropriate based on the results of the inspection.

Substrates, such as electronic device assemblies, that have been treated for the subsequent application of one or more protective coatings thereto are also disclosed. Without limitation, such an electronic device assembly may include two or more components with surfaces that have been modified to improve a quality of a protective coating that is to be applied to the modified surfaces. Some non-limiting examples of such a quality include the ability of the protective coating to adhere to the modified surface, a consistency of the protective coating (e.g., a lack of pores or other discontinuities, a consistent thickness, etc.) and the like.

Other aspects, as well as features and advantages, of various aspects of the disclosed subject matter will become apparent to those of ordinary skill in the art through consideration of the ensuing description, the accompanying drawings, and the appended claims.

### BRIEF DESCRIPTION OF THE DRAWINGS

In the drawings:

FIG. 1 is a schematic representation of an embodiment of an apparatus for applying a protective coating to a substrate, such as an electronic device assembly or a high volume of separate electronic device assemblies;

FIG. 2 is a schematic representation of an embodiment of a production or assembly line into which the apparatus of FIG. 1 has been integrated or incorporated;

FIG. 3 is a schematic representation of a production or assembly line for assembling an electronic device having a protective coating on one or more of its surfaces, features or components;

FIG. 4 is another representation of an embodiment of a production or assembly line that includes an off-line coating application element; and

FIG. 5 is a schematic representation of an embodiment of a production or assembly line that includes a disassembly element upstream of a coating application element.

### DETAILED DESCRIPTION

An apparatus according to this disclosure includes one or more elements for applying a protective coating to a substrate, such as an electronic device assembly.

As discussed in greater detail hereinafter, a plurality of components may be assembled into an electronic device assembly that is itself a portion of an electronic device or a complete electronic device. In its completed form, an electronic device may have an exterior that is susceptible to damage by moisture. Aspects of the present disclosure relate to apparatuses, systems and methods for applying a moisture resistant coating or another protective coating to mitigate such susceptibility. In some cases, a protective coating may be applied to interior surfaces, features or components of an electronic device assembly, either by applying the protective coating to individual components prior to their assembly with other parts of an electronic device, by applying the protective coating to assemblies of components prior to or during their assembly with other parts of the electronic device or even after assembly of the electronic device is complete, by disassembling one or more components from other components of the electronic device.

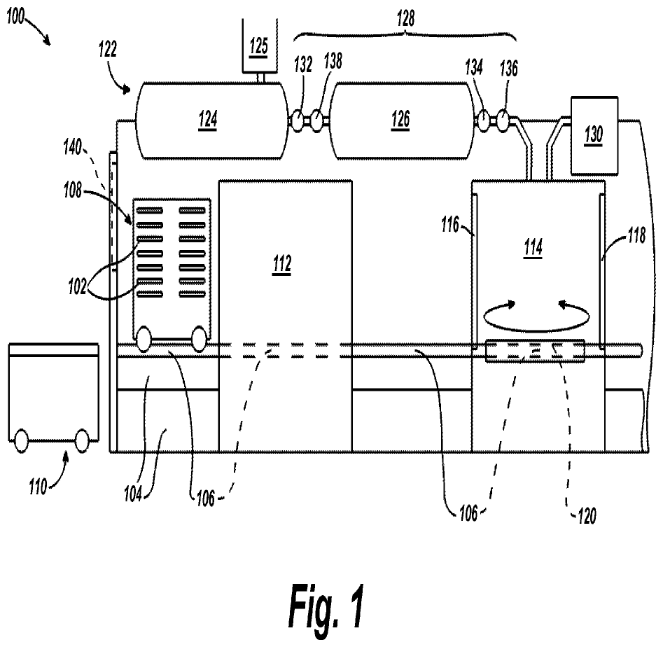

FIG. 1 illustrates an embodiment of an apparatus 100 for forming and/or applying a protective coating to one or more substrates 102. In at least some embodiments, the apparatus 100 may comprise a so-called “high throughput” apparatus, in which many substrates 102 may simultaneously have a protective coating applied thereto. As will be appreciated, the number of substrates 102 that may be processed at a single time may vary based on multiple factors, including the sizes of processed substrates 102. For instance, in some embodiments hundreds of substrates 102 (e.g., up to about one five hundred (500), between five hundred (500) and one thousand (1,000), or even more than one thousand (1,000) substrates), etc.) may be simultaneously coated. In the same or other embodiments, the effective per-substrate coating time may also be a matter of seconds (e.g., thirty seconds or less, twenty seconds or less, ten seconds or less, five seconds or less, etc.), although in other embodiments the coating time may be greater than thirty seconds or less than five seconds. High throughput for applying protective coatings to hundreds of (e.g., five hundred or more) substrates may be performed for one type of device; however, other devices processes using the same equipment may have lower throughput.

Although not necessary for all embodiments, the apparatus 100 may thus be configured to apply protective coatings concurrently to a plurality of substrates 102. In some embodiments, and without limiting the scope of the disclosed subject matter, an apparatus 100 may be configured to form protective coatings or films on electronic device components during their assembly. In other embodiments, the apparatus 100 may be configured to form a protective coating or film on components intended for assembly with other components that will form an electronic device, but that are not yet part of an electronic device assembly, or even following disassembly of all or a portion of an electronic device.

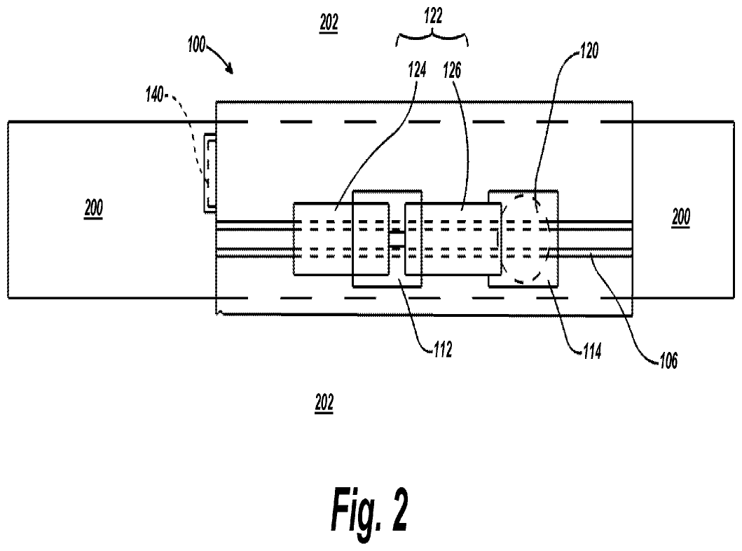

In some embodiments, such as where the substrate 102 is an electronic device assembly and the apparatus 100 forms a moisture resistant or other protective coating during assembly, the apparatus 100 may include a support structure for carrying some or all of its other components. The apparatus 100 includes, for instance, a frame 104 that may be configured for incorporation into an assembly line. An example assembly line 200 into which the apparatus 100 may be incorporated is shown in FIG. 2. In some embodiments, the apparatus 102 may be configured to fit into the assembly line 200 without protruding a significant distance into aisles 202 on either side of the assembly line 200. Such an embodiment may be configured for incorporation into an assembly line 200 without blocking or otherwise impeding movement along either or both of the aisles 202 that are adjacent to the assembly line 200, or requiring that the assembly line 200 be moved or significantly restructured to accommodate the apparatus 100. In other embodiments, the apparatus 100 may significantly block or impede movement along one or more of the aisles 202.

An apparatus 100 may include a conveyor for transporting one or more substrates 102 along or through the apparatus 100. In embodiments where the apparatus 100 includes a conveyor (as opposed to embodiments where an element separate from the apparatus 100 is used to convey one or more substrates 102), operation of the conveyor may be manual or automated. In the illustrated embodiment, which should not be considered to limit the scope of conveyors that may be used in the apparatus, the conveyor comprises a track 106 configured to transport a complementarily configured rack 108, which, in turn, is configured to carry one or more substrates 102 through the apparatus 100. In the illustrated embodiment, the track 106 is oriented along the length of the frame 104 of the apparatus 100.

A separate cart 110 may carry the rack 108 to the track 106, and in some embodiments the cart 110 may be incorporated into an assembly line (e.g., assembly line 200) connecting the apparatus 100 to additional components or processes within an assembly line. To enable movement of the rack 108 from the cart 110 to the track 106, the track 106 may be positioned (e.g., at a location, at an elevation, etc.) that enables the cart 110 to be brought into a position adjacent the track 106 and to readily receive the rack 108 from the cart 110. When used in combination, the cart 110, the track 106 and the rack 108 may enable movement of substrates 102 throughout the apparatus 100 as well as throughout an assembly facility, thereby enabling the apparatus 100 to be used as part of the assembly line 200 or to be moved or used separately from the assembly line 200 (e.g., as part of a disassembly line and/or re-assembly line, as part of a supplier system where components with protective coatings are provided to third parties for assembly, etc.)

In some embodiments, the apparatus 100 for applying a protective coating may include a treatment element 112. In embodiments where the apparatus 100 also includes a track 106, the track 106 may pass through or into the treatment element 112 and the treatment element 112 may be configured to accommodate the rack 108. A treatment element 112 may be configured to clean or otherwise treat the substrate 102. For instance, in a particular embodiment, the treatment element 112 may be a de-gas element that facilitates the release and/or capture of volatile compositions that may be present on a substrate 102 (e.g., flux from an electronic device assembly, moisture, etc.). The treatment element 112 may be configured to operate while limiting exposure of the substrates 102 to the environment in which the apparatus 100 is located. For instance, the treatment element 112 may lack doors, ports, windows or similar structures that can open to expose the interior to the environment.

De-gassing or other treatment within the treatment element 112 may occur in any suitable manner. For instance, in one embodiment the substrates 102 are exposed to ultraviolet (UV) radiation and/or ozone, or a pressure change (e.g., decrease) may occur within the treatment element 112. Changing the pressure or exposing the substrate to UV radiation or ozone may be used to remove, drive-off or neutralize flux, solvents, oils, contaminants, or other materials. For instance, additional materials that may be de-gassed include organic materials such as skin oils and compounds from potting materials. The electronic components themselves, housings, and other components and/or materials may also be degassed. In one particular embodiment, de-gassing may include use of nitrogen within the treatment element 112. Nitrogen may be introduced into the treatment element 112 and taken to a desired temperature and pressure (e.g., 1 Torr or 133.3 Pa). The temperature and/or pressure may then be taken back to a normal temperature, which can act to remove or neutralize residual flux or other contaminants. In some cases, the materials that are removed or neutralized, if left untreated, may create a risk that a protective coating could delaminate, thereby reducing the effectiveness of the protective coating.

Removal of flux or other de-gassing is only one example of a treatment process or technique that may be used in conjunction with the treatment element 112. A treatment element 112 may be configured to clean, manipulate, or otherwise treat substrates 102 in any number of other manners. In the same or alternative embodiments, the treatment element 112 (or an additional treatment element) may treat surfaces of the substrate 102 to have one or more desired characteristics. Such treatment may include application of a surface preparation process in which all or selected surfaces are treated to, for instance, promote adhesion of a protective coating or enhance the hydrophobicity of a coating. De-gassing and cleaning a surface may generally be considered surface preparation processes as they may address contaminants or other materials that, if untreated, could resist initial or continued adhesion of a protective coating. In an example embodiment, a surface may also be activated. For instance, surface oxidation may be removed to activate a surface and/or a cleaning process (e.g., the application of a plasma, etc.) may be performed to dispose of or neutralize organic materials on the cleaned surface. Example processes that may be used to alternatively or additionally promote adhesion may therefore include plasma cleaning, oxidation (e.g., to oxidize process oils or other potential contaminants), or evaporation. Still additional processes may include using surface texturing using micromachining, etching (e.g., chemical or laser etching), or other processes. An additional example of a treatment process may include passivating desired surfaces by, for instance, applying a shielding material to make the surface(s) passive relative to environmental factors, which can reduce oxidation.

In some embodiments, treatment of the substrates 102 using the treatment element 112 may include physical application of chemicals or other materials. When such materials are applied, they may be applied in any suitable manner, including using a spray (e.g., spray gun or nozzle), deposition, evaporation, brush-on, dipping/dunking, or other physical application technique. Chemical additives (e.g., boron nitride, molybdenum disulfide, etc.), polymers, adhesives, or other materials may be applied in any of the above or any other suitable manner. Moreover, any of the treatment techniques herein may be performed manually using a human operator associated with the apparatus 100, or may be automated (e.g., using a multi-axis CNC machine). Combinations of manual and automated processes may also be used.

Regardless of the particular treatment to be performed within treatment element 112, the treatment may be applied selectively or non-selectively. In a non-selective example, one or more cleaning or other treatment techniques or processes can be applied to all exposed surfaces of the substrate 102. In contrast, a selective treatment process may be used to apply a treatment to less than all of the exposed surfaces, or to at least temporarily cover some surfaces, or reduce adhesion of some surfaces, such that only portions of the substrate 102 are treated. Particular, illustrative processes that may be applied selectively or non-selectively include plasma etching, chemical etching, laser etching (e.g., with a controllable beam for selective application.), silane exposure, or other treatments. In accordance with some aspects, silane exposure may be used to perform any number of different treatments. For instance, some silanes may be used as coupling agents to promote adhesion. A silane coupling agent may therefore act like a primer. In other embodiments, some silanes may act as moisture scavengers to convert water molecules to alcohol molecules. Example organotrialkoxysilanes may be used and can act as sealants against moisture. As another example embodiment, some silanes (e.g., organofunctional alkoyxsilanes) can react with organic polymers that are present or later become present. Such silanes can react with moisture to crosslink the silane into a stable structure and add durability, water or heat resistance, and the like. In still other embodiments, a selective treatment process may include using a mask to restrict what surfaces of the substrate 102 are exposed to treatment and/or to a subsequent application of a protective coating.

A mask, a coating release element or any other technique for enabling selective application and/or removal of protective coating may be provided in any number of suitable manners. For instance, an adhesive film (e.g., a tape, etc.), a hot melt adhesive, a photoimageable material, a micro-soap or the like may be applied to portions of a substrate to prevent a treatment from being effective on such surface and/or to prevent a coating from adhering to the surface. Additional masks may be applied using a reusable mold, a spray-on masking agent, a heat-shrink masking agent, a chemical masking agent, or any other suitable masking agent.

Following treatment, a substrate 102 may be immediately introduced into a coating element 114 of the apparatus 100. Alternatively, the substrate 102 may be temporarily held (e.g., for two (2) hours or less, for one (1) hour or less, for thirty (30) minutes or less, for five (5) minutes or less, etc.) between treatment and its introduction into the coating element 114. In some embodiments, the substrate 102 may be temporarily held so as to allow additional treatment to occur (e.g., using one or more additional online or offline treatment processes).

Regardless of whether or not the apparatus 100 includes a treatment element 1112, once each substrate 102 is ready to be coated, the respective substrate 102 may be introduced into the coating element 114 of the apparatus 100. In embodiments where the apparatus 100 includes a track 106, the coating element 114 may be positioned along the track 106, or the track may be configured transport a rack 108 into and out of the coating element 114.

Isolation of the substrates 102 from the environment external to the apparatus 100 may, in some embodiments, be desirable while applying a protective coating or film to one or more substrates 102. Isolation of the substrates 102 from the environment external to the apparatus 100 may be desirable during a treatment process, a coating process, any combination of treatment and/or coating processes or for an entire series of treatment and coating processes. If access is desired to the interior of the coating element 114 (or a treatment element 112), a door may enable selective control over access to the interior of the coating element 114 and, thus, enable isolation of substrates 102 therein from the external environment. In some embodiments, a coating element 114 (and/or a treatment element 112) may include a door through which one or more substrates 102 are introduced into and removed from the interior of the coating element 114 (and/or a treatment element 112). Alternatively, a coating element 114 (and/or a treatment element 112) may include more than one door. In a specific embodiment, an entry door 116 at one side of the coating element 114 may provide access to its interior, while an exit door 118 at an opposite side of the coating element 114 may facilitate the removal of the one or more substrates 102 from within the coating element 114. In some embodiments, the coating element 114 and its interior may be cube-shaped, and any doors 116, 118 may be substantially flat or planar when in a closed position. In other embodiments, the coating element 114 may have rounded surfaces. For instance, the coating element 114 may by cylindrical, spherical, semi-spherical, or have other rounded shapes, or have any combination of the foregoing.

A coating element 114 may include a rotatable platen 120, which may rotate substrates 102 or a rack 108 carrying one or more substrates 102 as a protective coating or film is deposited or otherwise formed on each substrate 102. The rotatable platen 120 may enhance the uniformity with which a coating forms on each substrate 102.

In embodiments where the coating element 114 includes an entry door 116 and the apparatus 100 includes a treatment element 112, the coating element 114 may be spaced apart from the treatment element 112. Such an arrangement may provide for accessibility to the entry door 116 in the event that such entry door 116 opens outward or access to the interior of the coating element 114 is otherwise desired or needed (e.g., during maintenance, for repairs, etc.).

In some embodiments, the coating element 114 may comprise a deposition element. A deposition chamber may be used where, for example, the protective coating or film that is to be applied to one or more substrates 102 comprises a polymer. Example polymers that are contemplated for application using the apparatus 100 include poly (p-xylylene), or parylene, or another material that may be formed in manner similar to parylene.

With the substrate(s) 102 in the coating element 114 and, if appropriate (e.g., in at least some embodiments where the coating element 114 comprises a deposition chamber), the doors 116 and 118 of the coating element 114 may be closed. A other protective material may then be directed from a supply system 122 into the coating element 114. The supply system 122 may, in some embodiments, be located at a higher elevation than, or even at least partially over, the track 106, the treatment element 112, if any, and/or the coating element 114. Such an arrangement may minimize the width of the apparatus 100. Of course, the supply system 122 and its components may be located elsewhere on the apparatus 100, including at one or more sides of the apparatus 100, and may jut or extend into the aisles 202 of the assembly line 200 of FIG. 2.

In embodiments where the protective material is deposited and/or polymerizes (e.g., where the material comprises poly (p-xylylene), etc.), the materials may be supplied to a deposition chamber of the coating element 114 by introducing a precursor material (e.g., paracyclophane or an analog thereof, which is also referred to in the art as a “parylene dimer,” etc.). Prior to introduction into the deposition chamber, the precursor material may be vaporized. The vaporized precursor material may then be subjected to pyrolysis or otherwise treated to create reactive species for introduction into the deposition chamber of the coating element 114.

In accordance with some embodiments, the supply system 122 of the apparatus 100 may thus include a vaporization chamber 124 and a pyrolysis chamber 126. In addition, the supply system 122 may include a valving system 128. A vacuum 130 may be associated with the coating element 114 to draw reactive species toward the substrate(s) 102 or to otherwise aid in the regulation of material flow, deposition and/or polymerization.

The vaporization chamber 124 may be configured to vaporize a precursor material, as discussed herein or as known in the art. In some embodiments, a vacuum 125 may be associated with and dedicated for use with the vaporization chamber 124. Such a vacuum 125 may prevent or restrict material from escaping the vaporization chamber 124 while the vaporization chamber 124 is open. The vacuum 125 may be used to regulate the pressure within the vaporization chamber 124. In one embodiment, such regulation may prevent pressure within the vaporization chamber 124 from exceeding safe limits while the vaporization chamber 124 is closed.

The pyrolysis chamber 126 may be associated with the vaporization chamber 124 in a manner that enables the vaporized precursor material to flow from the vaporization chamber 124 into the pyrolysis chamber 126. The pyrolysis chamber 126 may be configured to convert the vaporized precursor material into reactive species, which may ultimately be deposited onto a substrate 102 and polymerize to form a protective coating or film on the substrate 102.

Where a valving system 128 is included, the valving system may enable control of temperature, pressure or other conditions of the pyrolysis chamber while operation of the vaporization and/or deposition chambers is interrupted. A valving system 128 may also allow control of flow rates of material through the apparatus. The valving system 128 may include a first stop valve 132 between the vaporization chamber 124 and the pyrolysis chamber 126. A second stop valve 134 may be positioned between the pyrolysis chamber 126 and the coating element 114. The valving system 128 may also include one or more control valves 136, 138, which may be used to control the rate at which materials flow into, through, or out of one or more elements of the supply system 122. In the illustrated embodiment, the first control valve 136 is located between the pyrolysis chamber 126 and the coating element 114. In addition, or even alternatively, the second control valve 138 may be located further upstream, such as between the vaporization chamber 124 and the pyrolysis chamber 126.

In use, a precursor material may be introduced into the vaporization chamber 124. As the precursor material is introduced, the temperature within the vaporization chamber 124 may drop and/or the pressure may be varied. Similar changes in the conditions of the pyrolysis chamber may be avoided by closing the first stop valve 132 while the vaporization chamber 124 is exposed to the environment outside of the apparatus 100. The first stop valve 132 may be reopened once the vaporization chamber 124 is closed, or after conditions (e.g., temperature, pressure, etc.) within the vaporization chamber 124 have returned to operationally acceptable levels.

During operation, the conditions within the vaporization chamber 124 vaporize the precursor material. The vaporized precursor material flows into the pyrolysis chamber 126, where conditions may convert the vaporized precursor material into reactive species. In embodiments where a protective coating of a poly (p-xylylene) is to be deposited, the reactive species may comprise p-xylylene species.

With the doors 116 and 118 of the coating element 114 closed, the reactive species may flow or be drawn into the coating element 114. Prior to opening one or both doors 116, 118 of the coating element 1114, the second stop valve 134 may be closed to enable adjustment of the pressure within the coating element 114 (e.g., from a relatively negative pressure to atmospheric pressure, etc.), which may prevent or limit the introduction of contaminants onto each substrate 102 when a door 116, 118 is opened. Closing the second stop valve 134 when at least one door 116, 118 of the coating element 114 is open may also isolate the pyrolysis chamber 126 from external variables and, thus, enable maintenance of conditions (e.g., temperature, pressure, etc.) within the pyrolysis chamber 126. Depending on the synchronization of acts performed by the apparatus 100 (e.g., when a precursor material is introduced into the vaporization chamber 124 at the same time the pressure in the coating element 114 is varied, while the coating element 114 is open, or at the same time a substrate 102 is introduced into or removed from the coating element 114, etc.), the first stop valve 132 and the second stop valve 134 may be closed at the same time, completely isolating the pyrolysis chamber 126 from external conditions.

Once a substrate 102 or group of substrates 102 has been introduced into the coating element 114, the doors 116 and 118 may be closed and, while the second stop valve 134 remain closed, the pressure within the coating element 114 may be reduced (e.g., by way of the vacuum 130, etc.). Once the pressure within the coating element 114 is the same as or within an acceptable level of the pressure within the pyrolysis chamber 126, the second stop valve 134 may be opened, reactive species may be permitted to flow into the coating element 114 to deposit onto and polymerize on the substrate(s) 102.

The rates at which material flows through and out of the supply system 122 may be controlled, at least in part, with one or more control valves 136, 138. The control valve 136 between the pyrolysis chamber 126 and the coating element 114 may control the rate at which the reactive species flow into the coating element 114. Similar control may be achieved with the control valve 138 between the vaporization chamber 124 and the pyrolysis chamber 126. In addition, the control valve 138 may enable regulation of the flow of vaporized precursor material from the vaporization chamber 124 to the pyrolysis chamber 126, independently from the flow of reactive species from the pyrolysis chamber 126 into the coating element 114.

In addition to the foregoing, an apparatus 100 may include one or more processing elements 140 (e.g., computers, processors, etc.), which may automate, regulate, or otherwise control the operation and synchronization of any or all components of the apparatus 100 or assembly line 200.

As discussed herein, the substrates 102 which are coated with a protective material may take any of a number of different forms and, in some embodiments can include electronic device assemblies. Where the substrate is an electronic device assembly, the coating may be formed on portions of electronic device components that are part of the assembly. Example components may include chips, boards, electrical connections (e.g., leads, contacts, etc.) and the like. Thus, by forming the coating on the electronic device assembly, some embodiments contemplate protecting electrical connections and components against moisture, contaminants or other materials.

Embodiments of the present disclosure may further be employed in connection with the assembly of an electronic device. FIG. 2, for instance, illustrates an example assembly line 200 which includes an apparatus 100 for applying a protective coating to substrates (e.g., electronic device assemblies or components). Although not illustrated, other components of the assembly line 200 may include components for producing the electronic device assembly, inspecting the protective coating and/or electronic device assembly, testing the electronic device assembly, and the like.

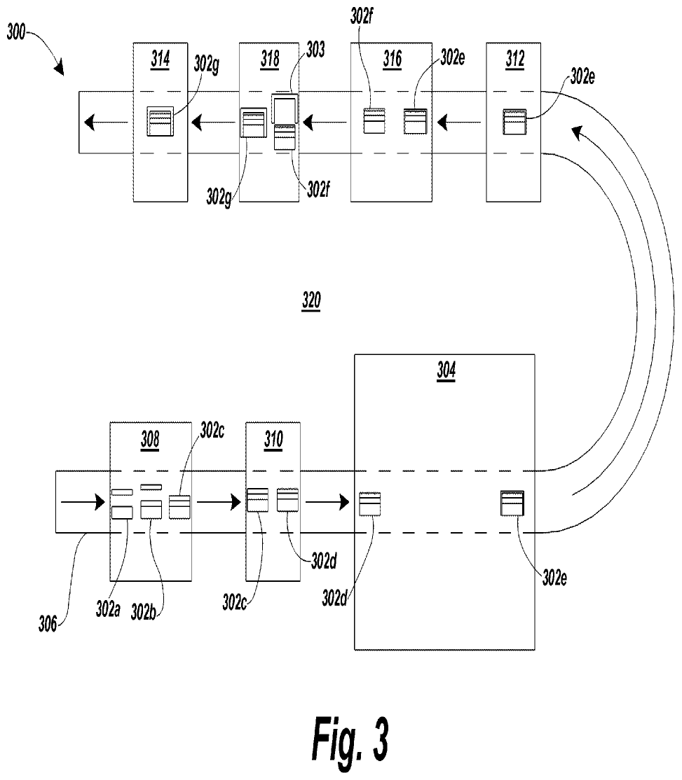

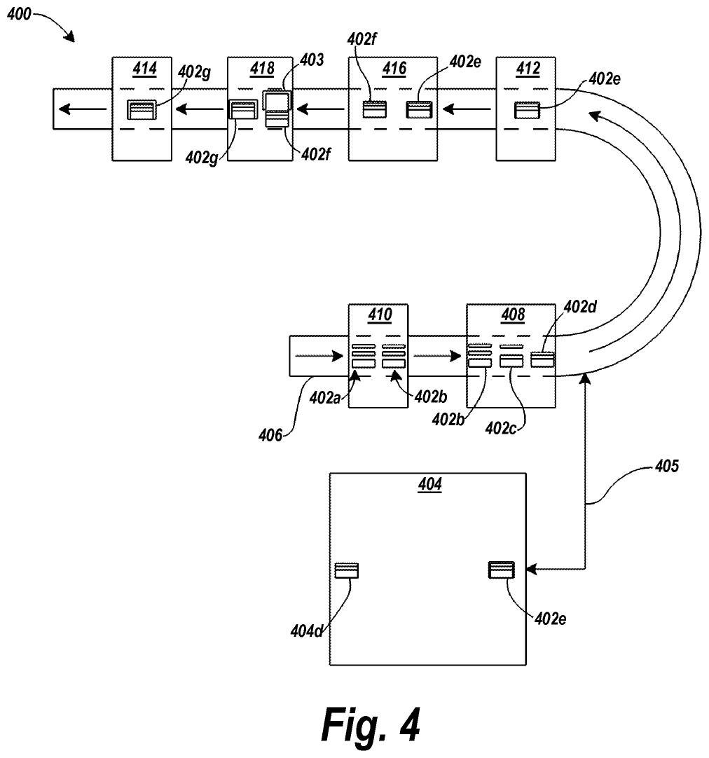

FIGS. 3 and 4, for instance, schematically illustrate examples of assembly systems 300, 400 in which an electronic device assembly may be produced and protected using a protective coating. In particular, FIG. 3, illustrates an assembly system 300 in which a coating may be applied to an electronic device assembly 302 using an in-line coating element 304, whereas FIG. 4 illustrates an assembly system 400 in which a coating may be applied to an electronic device assembly 402 using an off-line coating element 404. In either embodiment, the coating element 304, 404 may have a number of suitable forms, including that of the apparatus 100 described herein, as well as apparatuses that lack treatment functionality, but are configured to apply protective coatings.

With respect to FIG. 3, the example assembly system 300 is shown to include a conveyor 306 that may be used to transport substrates under assembly. The conveyor 306 may be used to transport substrates such as electronic device assemblies 302 from one or more optional assembly elements 308 and/or treatment elements 310 (e.g., pre-treatment elements, etc.) to the coating element 304. The same or a different conveyor 306 may also be used to transport electronic device assemblies 302 from the coating element 304 to or through one or more inspection elements 312, 314, treatment elements 316 (e.g., post-treatment elements, etc.), or further assembly elements 318. The conveyor 306 may comprise part of an assembly line, or it may include elements that enable it to carry one or more electronic device assemblies 302 away from an assembly line (which may include any or all of the components of assembly system 300) to an off-line coating element 304 (see FIG. 4) or optionally to other off-line components of the assembly system 300) and back to the assembly line.

The conveyor 306 may include a number of components for transporting one or more electronic device assemblies 302 to and from various components of the system 300. By way of illustration, a track may be used similar to the track 106 of the apparatus 100 of FIGS. 1 and 3, although other conveyor systems may be used. In some embodiments, the conveyor 306 is configured to be the same as, or link into, the track of a coating element 304 to allow the coating element 304 to operate in-line with other components of the assembly system 300.

In embodiments where one or more elements of the assembly system 300 prevent the constant movement of each electronic device under assembly through the assembly system 300 (e.g., while electronic device assemblies 302 are being coated using the coating element 304), the conveyor 306 may be associated with a controller to manage throughput. An example controller may include the processing elements 140 of FIG. 1, although a suitable controller may also be external relative to a coating apparatus or element. Moreover, in such embodiments, the conveyor 306 may include a collection component configured to collect a plurality of electronic device assemblies 302 prior to their treatment by one or more components that inhibit constant throughput (e.g., for the coating element 304 which may perform batch processing.), and potentially to feed the electronic device assemblies 302 into a particular element. In some embodiments, electronic device assemblies 302 may be produced or treated at some elements along the conveyor 306 at a rate that is different that a rate at other elements along the conveyor 306. As an illustration, a single electronic device assembly 302 may be produced at one time using the assembly element 308 (or a few may be simultaneously produced), while a much larger number of electronic device assemblies 302 may be simultaneously treated using the treatment element 310 or the coating element 304. Thus, in various embodiments, the components of the assembly system 300 may be synchronized to transport electronic device assemblies 302 through each element (and its corresponding components) at a desired rate. In a specific embodiment, such synchronization may be accomplished by way of programming executed by a controller, which, in turn, controls operation of various components of the conveyor 306; however, in other embodiments, manual operation may be used to direct all or some components (e.g., through input received at a user interface

As illustrated by FIG. 3, in some embodiments, a coating element 304 may be located upstream from the assembly element 308. In some embodiments, the assembly element 308 may access individual components of an electronic device assembly 302a and assemble the components. In the assembly element 308, for instance, two individual components from the electronic device assembly 302a may be connected to form an electronic device assembly 302b, and a third component may then be assembled to form the electronic device assembly 302c.

Assembly of the electronic device assembly 302c may occur using a number of suitable processes. For instance, devices connected in the electronic device assembly 302 may include a circuit board connected to a semiconductor component. Such assembly may occur using solder or any other suitable mechanism that electrically and physically connects the semiconductor component and circuit board. For instance, at the assembly element 308, solder may be used to electrically couple the semiconductor component to the circuit board (or to pads, leads or other terminals on the semiconductor component to corresponding pads, leads or other terminals of the circuit board), other types of intermediate conductive elements (e.g., leads, etc.) may also be used. In some embodiments, the connection may be automated and the assembly element 308 can thus include apparatuses that enable each semiconductor component to be properly positioned, electrically coupled and physically secured to the circuit board at an appropriate location.

The assembly element 308 may also apply a conductive material (e.g., aluminum, nickel, gold, solder, etc.) or other intermediate conductive element to various contact elements of the circuit board and/or semiconductor component. Any of a variety of different types of intermediate conductive elements may be secured to or formed on the contact elements, including, without limitation, solder halls, columns, pillars, leads (e.g., J-shaped leads, gull wing-shaped leads, etc.) or other structures formed from electrically conductive material, such as a metal, metal alloy, conductive epoxy, or the like; a so-called “z-axis” conductive film, which includes a dielectric substrate with discrete, electrically isolated conductive elements extending through the thickness of the dielectric substrate; and the like. In embodiments where intermediate conductive elements are formed from solder, screen printing apparatus, jet printing devices, and the like can be used to selectively apply solder paste (which includes solder and flux) to desired contact elements.

The assembly element 308 may also optionally include pick-and-place components to transport each circuit hoard and/or semiconductor component to an appropriate location on the conveyor 306 and/or within the assembly element 308. As the conveyor 306 transports each component, the pick-and-place components may assemble one or more components of the electronic device assemblies 302c. In some embodiments, once components are assembled, a coupling component of the assembly element 308 may be used. For instance, a solder reflow apparatus, such as a reflow oven, may be used, although other coupling components may be used to form the electronic device assembly 302c from the components shown in electronic device assembly 302a.

While assembly is described herein as including attachment of a circuit board to a semiconductor component, assembly at the assembly element 308 can include physical and/or electrical connection of any number of different components. For instance, representative components that may be assembled into the electronic device assembly 302c include electronic, user interface, and housing components. Such components and parts may be designed for autonomous or manual operation, or for a combination thereof.

As an illustration, electronic parts may include bare or packaged semiconductor devices, parts sometimes referred to as “irregular” or “odd form” electronic components, temperature sensitive parts, modules, ancillary boards, antennas, input devices (e.g., microphones, cameras, touch-sensitive elements, etc.), output devices (e.g., speakers, display screens, headphone jacks, etc.), ports (e.g., for battery charging, for communication, etc.), flashes (lights), proximity sensors, silent mode components and even electronic circuit components (e.g., resistors, capacitors, inductors, diodes, etc), as well as other components, or any combination of the foregoing. Such electronic components may be assembled and electrically coupled in any suitable manner, including to a circuit hoard or other electronic part. Soldering, welding, laser beam joining, focused infrared beam joining, localized convection, plug-in connectors, and other assembly techniques may be used within assembly element 308.

Example user interface components that may be connected as part of the electrical device assembly 302c may include features and components such as buttons, knobs, switches, keyboards, display covers and the like. Additional components, including batteries, cables, housing components and other components, may further be assembled at one or more assembly elements 308 using manual elements, automated elements, or a combination thereof.

Following assembly, the electronic device assembly 302c may be transported using the conveyor 306. In the illustrated embodiment, the electronic device assembly 302c may be transported to, and introduced into, a treatment element 310. In the treatment element 310, one or more surfaces of the electronic device assembly 302c may be treated prior to introduction of the electronic device assembly 302c into the coating element 304.

The treatment element 310 may apply any of a number of different types of treatments to the electronic device assembly 302c received from the assembly element 308. Examples of suitable treatments are discussed herein, and can include cleaning, washing, drying, forming a surface texture, passivating one or more surfaces, or otherwise treating the electronic device assembly 302c. In some embodiments, the assembly system 300 may include a plurality of treatment elements 310, which may perform the same functions as one another or different functions from one another. In embodiments, where an assembly system 300 includes a plurality of treatment elements 310, one or more electronic device assemblies 302c may be subjected to one or more treatment processes. Different treatment elements 310 of the assembly system 300 may operate at the same time as (i.e., in parallel with) one another. Treatment elements 310 that operate in parallel with one another may treat different electronic device assemblies 302c or groups of electronic device 302c assemblies in the same way as each other (i.e., the same process), or in different ways.

In some embodiments, the assembly process used by assembly element 308 may result in residual flux residing on the electronic device assembly 302c. A treatment element 310 may be configured to de-gas the electronic device assembly 302c, apply ozone or UV radiation, thermally treat or otherwise treat the electronic device assembly 302c to remove or neutralize (e.g., by decreasing the deleterious effects of contaminants by degreasing, oxidation, vaporization, disintegration., physical movement, etc.) the residual flux or other oils, greases, volatile materials, or other contaminants. Such treatment may reduce oxidation risk and/or promote adhesion of a coating by reducing a risk that the coating delaminates. As also discussed herein, the treatment may be selectively applied to some surfaces of the electronic device assembly 302c or may be non-selectively applied to all exposed surfaces of the electronic device assembly 302c. Indeed, in some embodiments, the treatment element 310 may act to mask or select some surfaces to be treated by a subsequent treatment element or by a treatment chamber within the coating element 304.

Thus, in accordance with some embodiments, the treatment element 310 may include masking apparatuses or systems. Masking may be configured to prevent or limit where a coating is applied. For instance, a coating may not be desired for some surfaces (e.g., on electrical contacts, where intermittent mechanical connection is desired, on optical elements (e.g., a camera lens, a display, etc.), etc.), and such surfaces may be covered or masked. Some embodiments comprise physically masking elements to which a protective coating is to be applied, whether before or after assembly, while other embodiments contemplate depositing a selectively removable temporary mask onto a component to which a protective resistant coating is to be applied.

An assembly system 300 that treats electronic device assemblies 302 by masking portions thereof, may also include a treatment element 316 to optionally de-mask elements downstream from the coating element 304 to expose features that have been masked and which do not have a protective coating adhered thereto.

Treatment element 310 may thus be broadly considered to apply a type of surface treatment to one or more portions of an electronic device assembly 302c, and to prepare a surface of the electronic device assembly 302c for application of a protective coating. As discussed herein, in some embodiments, a treatment element 310 may be configured to enhance adhesion of a protective coating by providing a modified surface. Such modified surface may be freed of contaminants or volatile contaminants, may be treated to have a desired characteristic (e.g., water repellency, such as a so-called “lotus leaf” structure or texture, etc.), masked to expose some but not all surfaces, or the like.

In the illustrated embodiment, the electronic device assembly 302c is treated within the treatment element 310 to produce a treated electronic device assembly 302d. The treated electronic device assembly 302d is then passed to the coating element 304 using the conveyor 306. In an example embodiment, the coating element 304 may be configured to apply a protective coating (e.g., of Parylene C, etc.) to each electronic device assembly 302d, including to any circuit board, chip, communication contact, power supply (e.g., battery, etc.), or the like that may be integrated with, or assembled on, the treated electronic device assembly 302d, to produce a coated electronic device assembly 302e. The coating element 304 may be similar or identical to the coating apparatus 100 of FIGS. 1 and 2, although it may also differ therefrom.

The rate at which the protective coating is applied to the treated electronic device assembly 302d may be faster or slower than the rate at which the electronic device assemblies 302c are treated at the treatment element 310. Additionally, or alternatively, there may be a delay following treatment and coating. For instance, a capacity of the treatment element 310 may be less than a capacity of the coating element 304. Thus, there may be a delay while some treated electronic device assemblies 302d wait for a larger batch of treated electronic device assemblies 302 to be coated using the coating element 304. Of course, a similar occurrence may be present between any elements of the assembly system 300.

It will be appreciated in view of the disclosure herein that while the illustrated embodiment includes the coating element 304 downstream from the treatment element 310 and assembly element 308, such an embodiment is merely illustrative. Indeed, in other embodiments the coating element 304 may apply a protective coating to individual components prior to assembly 308 and/or treatment. Indeed, in embodiments where a coating has been applied to an electronic device assembly in advance of assembly, some or all of the reasons for treating the assembly may be eliminated (e.g., residual flux may not be present during coating to resist adhesion of the protective coating). Additionally, that rate at which the coating is applied prior to assembly may be faster than the rate at which the same coating material (e.g., Parylene C, etc.) may subsequently be introduced between the components of the electronic device assembly 302d, and may provide more reliable protective coating. In such embodiments, at least a portion of the protective coating may reside between components prior to assembly, and in some embodiments flux and/or other contaminants may be present on exposed surfaces of the coating.

While some reasons for treatment may be eliminated by performing coating prior to assembly, the electronic device assembly may none-the-less be treated following assembly. For instance, additional coatings may be applied. Indeed, the inclusion of two or more coatings may further optimize hydrophobic or other properties of coatings on critical features of the electronic device assembly 302c and, thus, within the interior of a finished electronic device. In some embodiments, the coating element 304 is positioned to apply a protective coating to exposed surfaces of an electronic device assembly 302c, or to components that are to be assembled with the electronic device assembly 302c, that will ultimately be located within an interior of, or internally confined within, a finished electronic device. In other embodiments, treatment after coating and prior to, during, or after assembly may be configured to expose contact elements (e.g., contact pads, terminals, etc.) covered by a coating.

The coating element 304 may comprise any of, or any combination of, a variety of embodiments of coating apparatuses. In a specific embodiment, the coating element 304 of an assembly system 300 may comprise an apparatus that forms reactive monomers, which monomers may then be deposited onto and form polymers on one or more surfaces that are to be protected. In specific embodiments, the coating element 304 may be configured to deposit polyp-xylylene) parylene), including unsubstituted and/or substituted units, onto one or more surfaces that are to be protected. Examples of coating elements that function in this manner are described by U.S. patent application Ser. Nos. 12/104,080, 12/104,152 and 12/988,103, the entire disclosures of each of which are, by this reference, hereby incorporated herein in their entireties. U.S. patent application Ser. Nos. 12/446,999, 12/669,074 and 12/740,119, the entire disclosures of all of which are, by this reference, hereby incorporated herein in their entireties, also disclose embodiments of equipment and/or processes that may be employed by a coating element 304 of an assembly system 300 to form protective coatings. Various embodiments of apparatuses that may be employed as a coating element 304 of an assembly system 300 include, without limitation, molecular diffusion equipment, chemical vapor deposition (CVD) equipment, physical vapor deposition (PVD) equipment, evaporation deposition equipment, (e.g., for e-beam evaporation, sputtering, laser ablation, pulsed laser deposition, etc.), plasma enhanced chemical vapor deposition equipment (PECVD), pulsed plasma deposition (PPD), atomic layer deposition (ALD), and physical application apparatuses (e.g., printing equipment, spray-on equipment, roll-on equipment, brush-on apparatuses, etc.). Of course, other embodiments of coating elements 304 may also be used in an assembly system 300.

Materials that may be applied by a coating element 304 of an assembly system 300 may include, but are certainly not limited to, thermoplastic materials, curable materials (e.g., radiation-curable materials, two-part materials, thermoset materials, room-temperature curable materials, etc.), and halogenated chemical materials (e.g., including those containing fluorides and chlorides). In some embodiments, the coating element 304 may be configured to apply a coating or film (or multiple layers of the same or different coatings or films) having a sufficient thickness to provide a desired level of protection within a relatively short period of time. In various embodiments, a coating element 304 may be configured to deposit a film (e.g., a Parylene film, etc.) having a minimum thickness or an average thickness of at least one micron in less than an hour, in about fifteen minutes or less, in about five minutes or less, or even in about two minutes or less.

In the context of an entire assembly system 300, a plurality of different coating elements 304, and even different types of coating elements 304, may be located to provide desired types of coatings on different types of features. Without limitation, one coating element 304 may be configured to provide a protective coating in small spaces between different components of an electronic device assembly 302, while another coating element 304 may be configured to provide a conformal, blanketed protective coating on surfaces that are exposed during the coating process, and another coating element 304 may selectively apply a protective coating to certain features.

An assembly system 300 may include at least one inspection element 312. For instance, the inspection element 312 may be a coating inspection element within or downstream from the coating element 304. The coating inspection element 312 may enable an analysis of the presence of a protective coating, the thickness of the protective coating, the surfaces on which the protective coating resides, the quality of a protective coating, or any other useful information about a protective coating that has been applied by a coating element 304 to an electronic device assembly. Information from a coating inspection element 312 may be used to provide feedback control over a coating element 304 associated with the inspection element 312 or over any other component of the assembly system 300.

In some embodiments, an assembly system 300 may include a treatment element 316. The treatment element 316 may be configured to selectively or non-selectively treat a coated electronic device assembly 302e having a protective coating thereon. Such treatment may vary. For instance, as discussed herein, the treatment element 310 may apply a mask to selected portions of an electronic device assembly, and the treatment element 316 may optionally remove all or a portion of a mask. In other embodiments, the treatment element 316 may selectively remove one or more regions of a protective coating from the coated electronic device assembly 302e. Such material removal may be effected by any suitable means, without detrimentally affecting underlying or adjacent portions of the electronic device under assembly from which the material is removed. As an example the treatment element 316 may be configured to ablate, vaporize or sublimate the material of the protective coating (e.g., with a properly placed, pulsed or continuous laser beam, etc.). As another example, the treatment element 316 may selectively apply a solvent (e.g., by inkjet processes, screen printing, etc.) that will selectively remove a portion of the protective coating on an electronic device assembly 302e. In yet another example, the treatment element 316 may be configured to mechanically remove material from one or more selected regions of a protective coating (e.g., by cutting, abrading, etc.). In FIG. 3, for instance, the coated electronic device assembly 302e may have a protective coating applied to all exposed surfaces, including top or side surfaces. In one embodiment, treating the electronic device assembly 302e may include removing portions of the coating (e.g., coating on one or more side surfaces) to produce an electronic device assembly 302f. In still other embodiments, the treatment element 316 may clean, dry, or otherwise treat a coated electronic device assembly 302e to produce an electronic device assembly 302f.

As discussed herein, the electronic device assembly 302f may be all or a portion of an electronic device. In some embodiments, the electronic device assembly 302f may be a portion of a complete electronic device and additional assembly may be needed to physically and/or electrically connect the electronic device assembly 302f to one or more other components to form the full electronic device. In FIG. 3, the assembly system 300 includes an additional assembly element 318 to further assemble the electronic device assembly 302f following application of a protective coating. In this particular embodiment, a further component 303 may be attached to the electronic device assembly 302f to form a more fully assembled electrical device assembly 302g, which may also be a fully assembled electrical device. The assembly element 318 may operate in a manner similar to the assembly element 308 described herein, and can include components for physically and electrically connecting electrical components, user interface components, housing components, and other components of an electrical device.

In accordance with at least one embodiment, after assembly of an electronic device assembly (whether before or after coating components thereof), an inspection element 314 may be provided. The inspection element 314 shown in FIG. 3 may, for instance, inspect the assembled electronic device assembly 302g to inspect its functionality, whether the assembly is completed, the efficacy of a coating on or within the electronic device assembly 302g, or for any other purpose. The inspection element 314 may enable an analysis to provide any useful information about the electronic device assembly 302, and may be used to provide feedback control over an assembly element 318, treatment element 316, or over any other component of the assembly system 300.

As shown in FIG. 3, an aisle 320 may exist between some or all components of the assembly system 300. In at least some embodiments, it is desirable to provide a space within the aisle 320 that is unobstructed so as to allow an operator to access one or more elements of the system 300. Such access may be to allow the operator to perform manual functions associated with the assembly, inspection, coating, treatment, or other handling of an electronic device assembly or other substrate, to repair or maintain equipment used in the assembly, inspection, coating, treatment, or other handling of an electronic device assembly or other substrate, or for other reasons.

In one embodiment, the coating element 304 and other elements may be sized to provide sufficient space for access within the aisle. For instance, the coating element 304 may be sized to allow between one half and five meters of clearance within the aisle. Such clearance may be provided even to the extent the coating element 304 is or includes a high throughput apparatus in which many electronic device components or assemblies, or other substrates, may simultaneously have a coating applied thereto. For instance, in some embodiments hundreds of substrates (e.g., up to about one five hundred (500), between five hundred (500) and one thousand (1,000), or even more than one thousand (1,000) substrates), etc.) may be simultaneously coated. In an example where the electronic device assemblies are components of a portable electronic device such as a portable phone, tablet computing device, camera, laptop, e-reader, portable music player, remote keyless entry system or the like, a considerable space may be required within the coating element 304 to simultaneously coat such a volume of the electronic device assemblies. Indeed, a coating chamber of the coating element 304 may be provided which has a measurement of about two or more feet in each of three dimensions. In at least one embodiment, for instance, a cubic deposition chamber may measure between about thirty and about fifty inches in each direction. As a more particular embodiment, an example deposition chamber may measure about forty inches high by about forty inches wide by about forty inches long.

In the assembly system of FIG. 3, a conveyor 306 may be used to transport electronic device assemblies 302 between different elements. In some embodiments, the conveyor 306 may represent a set of conveyors or other transport equipment that may transport electronic device assemblies 302 between different elements. Moreover, while the conveyor 306 is illustrated as providing sequential transport between elements, some embodiments may include a more complex system flow. For instance, rather than including multiple assembly elements 306, 316, a single assembly element may be provided to perform assembly before and after applying a protective coating to an electronic device assembly. Similarly, a single inspection element may be used rather than separate inspection elements 312, 314. In still additional embodiments, the conveyor 306 may allow different electronic device assemblies or components to be routed in different manners (e.g., some may be coated prior to assembly while others coated after assembly, some directed to one type of treatment element while others bypass or go to other treatment elements, etc.).

The conveyor 306 may also route electronic device assemblies 302 to some but not all elements. In accordance with one embodiment, FIG. 3 generally illustrates an embodiment in which the various elements are in-line and all processing of the assembly system 300 may be performed within the assembly line. In contrast, however, some elements may be fully or partially off-line. When off-line, a component or element may be removed from an assembly line for out-of-band processing. As an example, an electronic device assembly may be provided to a third party for application of a protective coating and thereafter returned. In a similar manner, a third party or other system may be used for inspection and/or continued assembly of an electronic device assembly.

FIG. 4 illustrates an assembly system 400 in which some or all electronic device assemblies may be at least partially processed off-line. In particular, in the illustrated embodiment, a coating element 404 is offline relative to an assembly line of the assembly system 404; however, any one or more other elements may also or alternatively be made off-line.

The assembly system 400 of FIG. 4 includes elements generally similar to those described above relative to the assembly system 300 of FIG. 3. Thus, to avoid unnecessarily and redundantly describing embodiments of the present disclosure, the disclosure of FIG. 3 should be understood as equally applicable to the assembly system 400 of FIG. 4. Nevertheless, for completeness, a few elements are modified as discussed hereafter.

In the assembly system 400, a conveyor 406 may be used to convey substrates in the form of electronic device assemblies 402 between some elements of the assembly system 400, including from a treatment element 410 (which may be used in a system where a coating element 404 is not physically coupled with a treatment element, in a system where the coating element 404 also includes a treatment element (e.g., for added treatment of a different type, etc.), etc.) to an assembly element 408 (e.g., in embodiments where treatment may occur before assembly and application of a protective coating, etc.), or from the assembly element 408 to the treatment element 410. Accordingly, the assembly system 400 illustrates an example embodiment in which components of an electronic device assembly 402 may be at least partially treated prior to assembly. In some embodiments, treatment may be performed both prior to and after assembly.

An electronic device assembly 402a may be treated to become a treated electronic device assembly 402b, and the treated electronic device assembly 402b can be assembled in any suitable manner using the assembly element 408. In the illustrated embodiment, individual components of the treated electronic device assembly 402a may be treated and thereafter assembled to form treated electronic device assemblies 402c and 402d. The assembled electronic device assembly 402d in FIG. 4 may then be taken off-line. For instance, a transport 405 may be used to remove the assembled electronic device assembly 402d and deliver it to a coating element 404. The coating element 404 may include all or portions of the apparatus 100 described relative to FIGS. 1 and 2, or may be any other suitable apparatus for applying a protective coating to a substrate such as an electronic device assembly 402.

After a protective coating is applied using the coating element 404, a coated electronic device assembly 402e may be removed from the coating element 404 using a transport 405 and returned to the assembly line of the assembly system 400. In the illustrated embodiment, this includes returning an electronic device assembly 402e to the conveyor 406 where it is subsequently delivered to an inspection element 412. The inspection element 412 may inspect the coating, the components of the electrical device assembly 402e, or otherwise perform an analysis related to electronic device assembly 402e. Thereafter, if desired, the coated electronic device assembly 402e may be delivered by the conveyor 406 to a treatment element 416. The treatment element 416 may produce a treated electronic device assembly 402f that can be further assembled (e.g., with a component 403) at an assembly element 418. Once assembled in to an electronic device assembly 402g, the assembly may optionally be inspected at an inspection element 414.

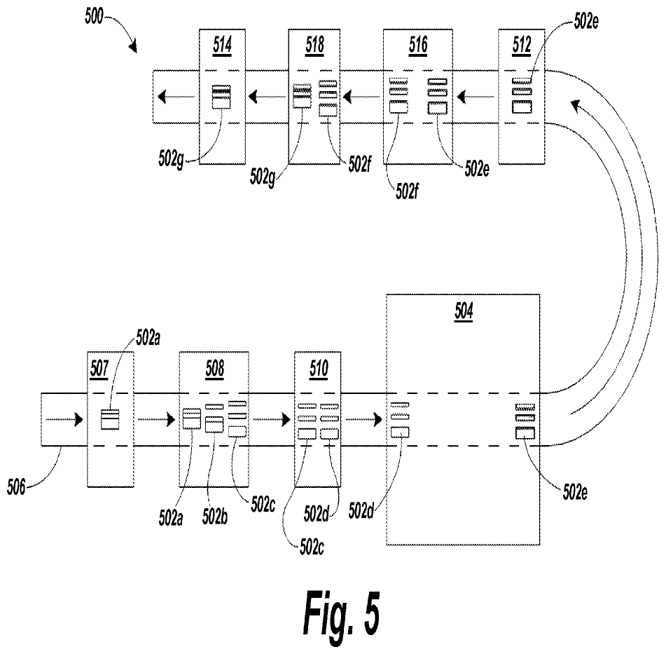

As reflected in the embodiments described relative to FIGS. 3 and 4, application of a protective coating to a substrate such as an electrical device assembly may be performed during an assembly process by which an electronic device (or components thereof) is produced. In other embodiments, however, an electronic device (or components thereof) that have already been assembled may benefit from application of a protective coating, including to potentially interior components or interfaces between components. Accordingly, some embodiments of the present disclosure relate to applying a protective coating to a disassembled electronic device. A discussion of an example production system related to such an embodiment is described relative to FIG. 5.

In FIG. 5, a production system 500 is illustrated and includes elements generally similar in many regards to those described herein relative to FIGS. 3 and 4. The illustrated embodiment is provided not to indicate that any element is required for any or all embodiments, but to illustrate that similar elements and components may be used in multiple configurations of an assembly or production system. As such elements may be similar or identical, the discussion of assembly systems 300, 400 should be understood as equally applicable to the production system 500 of FIG. 5. Nevertheless, for completeness, a few elements are modified or different from the discussion above, and are discussed in greater detail hereafter.

In the production system 500, a conveyor 506 may be used to convey substrates in the form of electronic device assemblies 502 between some elements of the production system 500, including from an inspection or identification element 507 to a disassembly element 508 and to a treatment element 510. Accordingly, the production system 500 illustrates an example embodiment in which components of an electronic device assembly 502 may be at least partially disassembled and treated prior to assembly. In some embodiments, treatment may be performed prior to and/or after disassembly of all or a portion of the electronic device assembly 502.

In the production system 500, an electronic device assembly 502 may have any number of different forms. For instance, as discussed herein, the electronic device assembly 502 may include a portable electronic device such as a cell phone, laptop, tablet computing device, camera, media player, e-reader, remote keyless entry system or the like. In other embodiments, the electronic device assembly 502 may be only a portion of an electronic device.

As shown in FIG. 5, the conveyor 506 of the production system 500 may be used to deliver an assembled electronic device assembly 502a to an initial element, which in some embodiments may include an inspection element 507. The inspection element 507 may be used to obtain information about the electronic device assembly 502a. Examples of information that may be obtained may include what type of device or assembly is provided, what components are included in the electronic device assembly 502a, the size and/or shape of the electronic device assembly 502a, whether the electronic device assembly 502a is fully or partially assembled, what types of connectors are used between components of the electronic device assembly 502a, and any other information. The analysis performed using the inspection element 507 may be performed manually or in an automated manner. For instance, a three-dimensional scanner may be used to identify the device and/or compare information obtained against information stored in a table or database to determine what device, components, and the like are included in the provided electronic device assembly 502a.

Information obtained at the optional inspection element 507 may be used to determine how to disassemble, treat, apply a protective coating, or otherwise handle the electronic device assembly 502a during processing in the production system 502. Thus, in some embodiments, the inspection element 507 may include or communicate with a controller or processor that may in turn communicate or control aspects of downstream elements.

Following inspection of the electronic device assembly 502a in the illustrated production system 500, the conveyor 506 may be used to deliver the inspected electronic device assembly 502a to a disassembly element 508. The disassembly element 508 may generally be used to detach, remove or otherwise disassemble some or all components that collectively make up the electronic device assembly 502a. Such components that may be detached, removed or otherwise disassembled may include housing components, user interface components and electrical components. For instance, in one embodiment, a housing element may be opened to expose interior components. Such interior components may be further disassembled, but need not be so. As an illustration, a battery may be removed or other components may be disconnected or removed, but in other embodiments such components may remain installed with a portion of an electronic device assembly while being detached relative to a portion of a housing or other component. In other embodiments, disassembly may be performed on other components and may or may not include disassembling housing elements. By way of example, a circuit board for use with an electronic device may be disassembled into two or more component parts.

The electronic device assembly 502a may include any number of different types of connections and disassembly element 508 may therefore use any number of mechanisms to disassemble the electronic device assembly 502a. Example disassembly mechanisms may, for instance, have the ability to detach snap, interference, frictional, plug-in or other fits or connectors that may secure components forming the electronic device assembly 502a. In other embodiments, other connectors may be detached. For instance, screws, clasps, latches, or other connectors may be detached using the disassembly element 508. In still other embodiments, components of the electronic device assembly 502a may be electrically coupled using solder or other similar mechanisms. In such embodiments, cables or wires may be cut or broken, or the solder or other material may be heated to allow components to be detached.

The disassembly element 508, regardless of the particular type of disassembly taking place, may therefore detach or change the position of one or more components of the electronic device assembly 502a. Such disassembly is schematically illustrated in FIG. 5 in which the electronic device assembly 502a is disassembled into electronic device assembly 502b and thereafter into electronic device assembly 502c. FIG. 5 illustrates each of three components being disassembled: however, it should be appreciated that there may be more or fewer than three components and that the illustrated components may represent a single component or may represent an assembly of multiple components. Thus, some but not all components may be disassembled, or the entire electronic device assembly 502a may be disassembled.

Once disassembled, the electronic device assembly 502c may be transferred using the conveyor 506 or another mechanism to a downstream treatment element 510 (although in some embodiments a treatment element 510 may be upstream relative to the disassembly element 508). At the treatment element 510, the components of the electronic device assembly 502c may be cleaned, washed, dried, de-gassed, re-surfaced, or otherwise treated. Examples of suitable treatments that may be applied are discussed in greater detail herein, and may include, in part, a treatment to remove or neutralize flux, oils, or other contaminants from all or a portion of the electronic device assembly 502c, application of a texture to all or some exposed surfaces within the electronic device assembly 502c, masking of all or a portion of the electronic device assembly 502c, and the like.

A single treatment or multiple treatments may be performed by the pre-treatment element 510 or by multiple treatment elements. In general, such treatments may be configured to enhance the ability of a protective coating to adhere to one or more surfaces of the electronic device assembly 502d, the efficacy of the protective coating, or for other purposes. Accordingly, some embodiments contemplate performing treatment prior to coating of the electronic device assembly 502d, as shown in FIG. 5.

Following treatment, the electronic device assembly 502d is optionally directed into the coating element 504. As discussed herein, the rates at which the conveyor 506 delivers electronic device assemblies 502 to various elements may vary. Thus, it should not be required that introduction into the coating element 504 immediately follow treatment by the treatment element 510. Instead, there may be a delay following treatment or the electronic device assembly 502d may even be routed to one or additional elements or locations for other processing prior to introduction to the coating element 504.

The coating element 504 may be configured to apply a protective coating to all or selected portions of the electronic device assembly 502d. The coating element 504 may include all or portions of the apparatus 100 described relative to FIGS. 1 and 2 (e.g., a coating element only, a treatment element and a coating element, etc.), or may be any other suitable apparatus for applying a protective coating to a substrate such as an electronic device assembly 502d. Consequently, in some embodiments, the coating element 504 may include both treatment and coating chambers or elements, although the coating element 504 need not include both such elements. Further, the coating element 504 may be a so--called high-throughput element in which many electronic device assemblies 502d are simultaneously provided with a protective coating. In a high-throughput coating element 504, there may be hundreds or even a thousand or more electronic device assemblies 502d that are simultaneously coated using the coating element 504. When multiple electronic device assemblies 502d are simultaneously coated, such electronic device assemblies 502d may be identical or they may be different (e.g., different models of phones, different types and sizes of devices, etc.).

Within the coating element 504, a protective coating is applied to the electronic device assembly 502d to obtain the electronic device assembly 502e, which has a protective coating on all or some surfaces. The coating may be applied selectively to some but not all surfaces exposed by disassembly (e.g., by pre-treating portions of an electronic device assembly to enhance or inhibit coating adhesion), or the coating may be applied non-selectively to any or all exposed surfaces. In some embodiments, the coating may be applied to exposed surfaces of components of the electronic device assembly 502d, including to contact elements (leads, contact pads, terminals, etc.) of such components.

Regardless of the particular manner in which the coating is applied, a coated electronic device assembly 502e may be removed from the coating element 504. In the illustrated embodiment, the coated electronic device assembly 502e is then transported using the conveyor 506 to an inspection element 512. In other embodiments, such as where the coating element 504 is off-line relative to a production line, a transport or other system may be used to return an electronic device assembly 502 to a production line.

The inspection element 512 may inspect the coating, the components of the electrical device assembly 502e, or otherwise perform an analysis related to the electronic device assembly 502e. Thereafter, if desired, the coated and disassembled electronic device assembly 502e may be delivered by the conveyor 506 to a treatment element 516. The treatment element 516 may produce a treated electronic device assembly 502f. Treatment by the post-treatment element 516 may include treatment as described herein or understood in view of the disclosure herein, including removal of material (including masking and/or coating materials), cleaning, washing, drying, or other treatments.

After treatment at the treatment element 516, the electronic device assembly 502f may thereafter be re-assembled into a physically and/or electrically connected assembly. Such re-assembly may occur by, for instance, reversing the processes performed by the disassembly element 508. In contrast, however, to the electronic device assembly 502a provided to the disassembly element 508, the reassembled electronic device assembly 502g may have one or more coatings applied to interior and/or exterior surfaces of the components of the electronic device assembly 502g. In some embodiments, the reassembly element 518 may be similar or identical to the assembly elements 308 and 408 of FIGS. 3 and 4, respectively. Following reassembly, the reassembled electronic device assembly 502g may be optionally inspected and/or tested at an inspection element 514.

As reflected in the embodiment described relative to FIG. 5, application of a protective coating to a substrate such as an electrical device assembly may be performed subsequent to assembly of the electronic device assembly. In at least some embodiments, full or partial disassembly may occur for application of the protective coating and may occur before or after treatment that also occurs prior to application of a protective coating.

Although the foregoing description provides many specifics, these should not be construed as limiting the scope of any of the appended claims, but merely as providing information pertinent to some specific embodiments that may fall within the scopes of the appended claims. Features from different embodiments may be employed in any combination. In addition, other embodiments may also be devised which lie within the scopes of the appended claims. All additions, deletions and modifications that fall within the meanings and scopes of the claims are to be embraced by the claims.

1-28. (canceled)

29. An apparatus for applying a parylene protective coating to an electronic device assembly, comprising:
a parylene coating application element comprising:
at least one door; and
an interior deposition chamber space,
the coating application element sized to simultaneously apply protective coating to a plurality of electronic device assemblies, wherein the coating application element is cuboid-shaped.

30. The apparatus of claim 29, wherein the interior deposition chamber space of the coating application element is cuboid-shaped.

31. The apparatus of claim 29, wherein the at least one door comprises an entry door and an exit door.

32. The apparatus of claim 31, wherein the entry door and the exit door are flat.

33. The apparatus of claim 32, wherein the exit door is positioned at an opposite side of the coating application element from the entry door.

34. The apparatus of claim 31, wherein the entry door and the exit door are planar.

35. The apparatus of claim 34, wherein the exit door is positioned at an opposite side of the coating application element from the entry door.

36. The apparatus of claim 29, wherein the at least one door and a frame of the coating application element form the interior deposition chamber space, wherein the interior deposition chamber space is cuboid-shaped.

37. The apparatus of claim 29, wherein the coating application element is cube-shaped.

38. The apparatus of claim 29, wherein the interior deposition chamber space is cube-shaped.

39. An apparatus for applying a parylene protective coating to an electronic device assembly, comprising:
a parylene coating application element comprising:
at least one door; and
an interior deposition chamber space,
the coating application element sized to simultaneously apply protective coating to a plurality of electronic device assemblies, wherein the coating application element is cube-shaped.

40. The apparatus of claim 39, wherein the interior deposition chamber space of the coating application element is cube-shaped.

41. The apparatus of claim 39, wherein the at least one door comprises an entry door and an exit door.

42. The apparatus of claim 41, wherein the entry door and the exit door are flat.

43. The apparatus of claim 42, wherein the exit door is positioned at an opposite side of the coating application element from the entry door.

44. The apparatus of claim 41, wherein the entry door and the exit door are planar.

45. The apparatus of claim 44, wherein the exit door is positioned at an opposite side of the coating application element from the entry door.

46. The apparatus of claim 39, wherein the at least one door and a frame of the coating application element form the interior deposition chamber space, wherein the interior deposition chamber space is cube-shaped.

47. An apparatus for applying a parylene protective coating to an electronic device assembly, comprising:
a parylene coating application element comprising:
at least one door; and
an interior deposition chamber space,
the coating application element sized to simultaneously apply protective coating to a plurality of electronic device assemblies, wherein the coating application element is hexahedron-shaped.

48. The apparatus of claim 47, wherein the interior deposition chamber space of the coating application element is hexahedron-shaped.
